(19) United States
(12) Patent Application Publication
(10) Pub. No.: US 2008/0064187 A1
(43) Pub. Date: Mar. 13, 2008

(54) Production Method for Stacked Device

(76) Inventor: Mark Brown, Los Altos, CA (US)

Correspondence Address: BRINKS HOFER GILSON & LIONE, P.O. BOX 10395, CHICAGO, IL, 60610, US

(21) Appl. No.: 11/848,840

(22) Filed: Aug. 31, 2007

(30) Foreign Application Priority Data
Sep. 13, 2006 (JP) 2006-248383

(51) Int. Cl. H01L 21/78

(52) U.S. Cl. 438/464; 257/E21.599

(57) ABSTRACT

A production method for obtaining a stacked device from a wafer is provided. The wafer has: a device forming region formed on a surface having plural devices formed thereon, the devices having surfaces and thicknesses; a peripheral extra region surrounding the device forming region; and plural metal electrodes embedded in the surfaces of the devices and having thicknesses which are equal to or larger than the thicknesses of the devices. The method includes: a protective tape applying process for applying a protective tape to the surface of the wafer; a rear surface recess forming process for thinning only a region, which corresponds to the device forming region, on a rear surface by grinding, thereby forming a recess on the rear surface, forming a ring-shaped protrusion projecting from the rear surface on the peripheral extra region, and exposing the metal electrodes at the rear surface; an etching process for removing mechanical damage, which is provided to the recess by the grinding, by etching to the recess, and forming a rear surface side electrode portion by projecting the exposed metal electrodes from a bottom surface of the recess; and a dividing process for dividing the wafer into the devices.

This application claims priority under 35 U.S.C. § 119 to Japanese Patent Application No. JP2006-248383 filed Sep. 13, 2006, the entire content of which is hereby incorporated by reference.

### BACKGROUND OF THE INVENTION

1. Field of the Invention

The present invention relates to a method for producing devices (for example, semiconductor chips) from a semiconductor wafer (for example, silicon wafer), in which the device has a metal electrode penetrating the device.

2. Description of Related Art

In recent techniques for semiconductor devices, a stacked semiconductor package (for example, a multi-chip package (MCP) and a system-in-package (SIP)) having plural stacked semiconductor chips is effectively used in order to have a high density and be compact and thin. For example, a production method for the semiconductor package is a method in which semiconductor chips are stacked on a package substrate which is called an “interposer”, electrodes of the interposer and the semiconductor chips or electrodes of the stacked plural semiconductor chips are electrically connected to each other by gold wires, and the semiconductor chips are resin-molded to the interposer.

However, in the above connection of the electrodes by the gold wires, the gold wires are deformed so that breakage of the wires and electrical short circuits occur when a resin for molding is sealed and the air remaining in the resin expands during heating so that breakage occurs. In order to solve the above problems, as disclosed in Japanese Unexamined Patent Application Publication No. 2005-166966 and Japanese Unexamined Patent Application Publication No. 2006-012889, a via electrode is provided to penetrate a semiconductor chip in a thickness direction of the semiconductor chip and connect to an electrode of the semiconductor chip, and the via electrode of one semiconductor chip is connected to that of another semiconductor chip when semiconductor chips are stacked to each other.

### SUMMARY OF THE INVENTION

In semiconductor chips connected by via electrodes, a rear surface of a semiconductor wafer, before a dividing process for dividing it into plural semiconductor chips, is subjected to grinding, and the semiconductor wafer is thereby thinned. As a result, via electrodes, which were previously formed in the wafer to correspond to the semiconductor chips, are exposed at the rear surface of the semiconductor wafer. Then, the rear surface of the semiconductor wafer is slightly removed by plasma etching, so that the via electrodes project from the rear surface of the semiconductor wafer. Since the via electrodes project in the above manner, the via electrode of one semiconductor chip can be reliably electrically connected to that of another semiconductor chip when semiconductor chips are stacked to each other. However, since the semiconductor wafer is processed to be very thin in the above manner so as to be compact and thin, it is difficult to handle the semiconductor wafer when moving it to an etching process after it has thinned and when moving it to a dividing process after the etching process. In addition, since the semiconductor wafer is easily broken, yield rate decreases.

Therefore, an object is to provide a production method for a stacked device, in which in producing devices (for example, semiconductor chips) having via electrodes, a thinned semiconductor wafer can have a rigidity thereof before a dividing process for dividing it into plural semiconductor devices and the thinned semiconductor wafer can be easily handled and can be smoothly moved between processes, so that productivity and yield rate can be thereby improved.

According to one aspect of the present invention, a production method for obtaining a stacked device from a wafer is provided. The wafer has: a device forming region formed on a surface having plural devices formed thereon, the devices having surfaces and thicknesses; a peripheral extra region surrounding the device forming region; and plural metal electrodes embedded in the surfaces of the devices and having thicknesses which are equal to or larger than the thicknesses of the devices. The method includes: a protective tape applying process for applying a protective tape to the surface of the wafer; a rear surface recess forming process for thinning only a region, which corresponds to the device forming region, on a rear surface by grinding, thereby forming a recess on the rear surface, forming a ring-shaped protrusion projecting from the rear surface on the peripheral extra region, and exposing the metal electrodes at the rear surface; an etching process for removing mechanical damage, which is provided to the recess by the grinding, by etching to the recess, and forming a rear surface side electrode portion by projecting the exposed metal electrodes from a bottom surface of the recess; and a dividing process for dividing the wafer into the devices.

In one aspect of the production method, only the rear surface of the device forming region of the wafer before the dividing process for dividing the wafer into the semiconductor chips is thinned by the grinding, and the initial thickness of the wafer is maintained on the peripheral extra region around the device forming region and the ring-shaped protrusion is thereby formed. Therefore, the wafer is thinned, but the rigidity of the wafer is ensured by the ring-shaped protrusion. Therefore, movement of the wafer to the etching process for forming the rear surface electrode portion by projecting the via electrode from the rear surface of the wafer and the etching process can be easily and smoothly performed. The movement of the wafer to the dividing process after the process can be safely performed without breaking the wafer. As a result, productivity and yield ratio can be improved.

According to a preferred embodiment of the present invention, the dividing process is performed while the rear surface of the wafer is exposed and held. According to a preferred embodiment of the present invention, the dividing process is performed after removing the ring-shaped protrusion on the peripheral extra region when the wafer is divided into plural devices by dicing the wafer by a cutting blade. Therefore, the wafer can be smoothly cut without the cutting blade interfering with the ring-shaped protrusion.

As is explained above, according to the present invention, the thinning of the wafer by grinding the rear surface is performed only at the region corresponding to the device forming region and the thick ring-shaped protrusion is formed on the peripheral extra region therearound, so that rigidity of the wafer can be obtained. As a result, the thinned semiconductor wafer can be easily handled and can be smoothly moved between processes, so that productivity and yield rate can be improved.

### BRIEF DESCRIPTION OF THE DRAWINGS

FIG. 1 is a perspective view of a wafer divided into semiconductor chips in a method of the embodiment according to the present invention. In FIG. 1, an enlarged portion shows a condition in which bumps project from surfaces of the semiconductor chips of the wafer.

FIGS. 2A to 2E are cross sectional views showing the outline of the method of the embodiment is shown in turn.

FIG. 3 is a cross sectional view showing an example of a semiconductor package having semiconductor chips produced by the method of the embodiment.

FIG. 4 is a perspective view of a cutting apparatus used in a process for making bump height uniform.

FIGS. 5A to 5C are cross sectional views showing the process for making bump height uniform in turn.

FIG. 6A is a perspective view of the wafer having a protective tape applied on a surface thereof by a protective tape applying process and FIG. 6B is a side view thereof.

FIG. 7A is a perspective view of a cutting apparatus used in a rear surface recess forming process and FIG. 7B is a side view thereof.

FIG. 8A is a perspective view of the wafer having a recess formed on a rear surface by the rear surface recess forming process and FIG. 8B is a cross sectional view thereof.

FIG. 9A is a plan view showing the rear surface of the wafer by the etching process and FIG. 9B is a perspective view showing the same.

FIG. 10 is a perspective view of a dicing apparatus used in a dividing process.

FIG. 11 is a perspective view of a laser machining apparatus used in a dividing process.

FIG. 12 is a perspective view showing a wafer held by a dicing tape so that a rear surface of the wafer is exposed.

FIG. 13 is a perspective view showing a wafer held by a dicing tape so that a surface of the wafer is exposed.

### DETAILED DESCRIPTION OF THE INVENTION

One embodiment of a production method for semiconductor chips using the present invention will be explained hereinafter with reference to the drawings.

### 1. Semiconductor Wafer

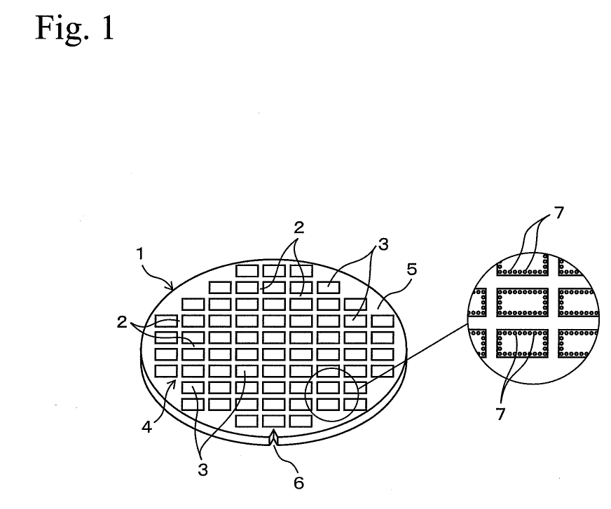

Reference numeral 1 in FIG. 1 denotes a disc-shaped semiconductor wafer (hereinafter referred to simply as a “wafer”) which is a material for producing semiconductor chips. For example, the wafer 1 is a silicon wafer having a thickness of about 600 μm. Plural rectangular semiconductor chips 3 (devices) are partitioned on the surface of the wafer 1 by grid-like predetermined division lines 2. An electronic circuit such as an IC (Integrated Circuit) or LSI (Large-Scale Integration) is formed on each surface of the semiconductor chips 3.

The plural semiconductor chips 3 are formed on a device forming region 4 having an approximately circular-shape which is concentric with the wafer 1. The device forming region 4 occupies most of the wafer. A ring-shaped peripheral extra region 5 on which the semiconductor chips 3 are not formed is a peripheral portion of the wafer around the device forming region 4. A V-shaped notch 6 indicating a crystal orientation of a semiconductor is formed at a predetermined portion of a circumferential surface of the wafer 1. The notch 6 is formed in the peripheral extra region 5.

As shown in FIG. 1, plural bumps 7 are formed on the surface of each semiconductor chip 3. The bumps 7 are projecting electrode portions for connecting to outer portions, and are applied to metal electrodes 8 electrically connecting to an electrode portion in the semiconductor chip 3. In the embodiment, the wafer 1 shown in FIG. 1 is cut and divided along the predetermined division lines 2, so that the plural semiconductor chips 3 are obtained.

### 2. Outline of Production Method

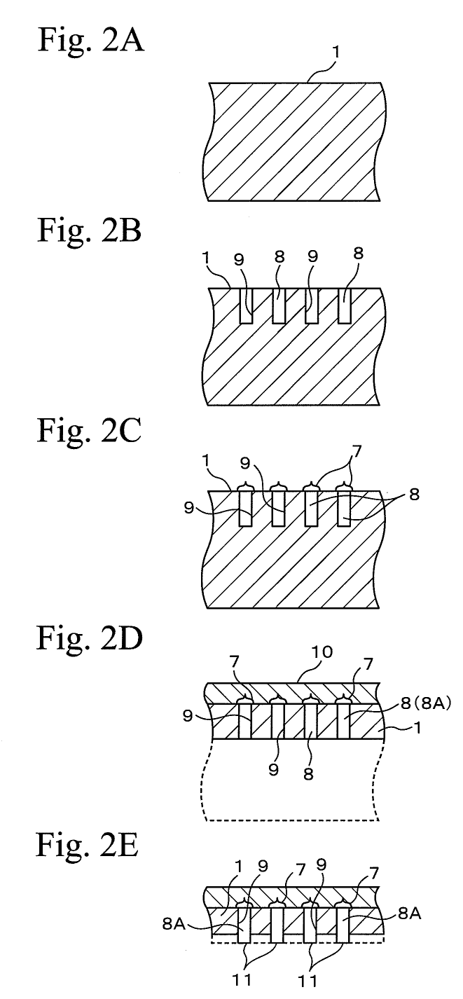

In the production method of the embodiment, first, as shown in FIG. 2B, plural metal electrodes 8 are embedded in a surface of a wafer 1 shown in FIG. 2A. The metal electrodes 8 will be formed into via electrodes 8A penetrating the wafer 1 by a post-processing. The depth of each metal electrode 8 is larger than the thickness of the semiconductor chip 3. The metal electrodes 8 are formed by embedding an electrode metal composed of copper into via holes 9 formed on the surface of the wafer 1. For example, the via holes 9 are formed by plasma etching at the surface of the wafer 1 on which a mask is formed by a resist pattern. For example, the metal electrodes 8 are formed in the via holes 9 by a chemical vapor deposition (CVD) method.

Next, as shown in FIG. 2C, the bumps 7 are applied to end surfaces of the metal electrodes 8 exposed at the surface of the wafer 1. The bumps 7 are applied by a method in which melted metal contacts the exposed surfaces of the metal electrodes 8, tips of the bumps 9 are sharp and have heights that are not equal to each other. The heights of the bumps 7 are adjusted by uniformly cutting off the tips of the bumps 9 after the bumps 7 are applied to the metal electrodes 8.

Next, as shown in FIG. 2D, a protective tape 10 covering the bumps 7 of which the heights of the bumps 7 are adjusted is applied to the surface of the wafer 1. After that, the wafer 1 is thinned by grinding a rear surface of the wafer 1, so that the metal electrodes 8 are exposed at the rear surface of the wafer 1. The protective tape 10 is applied to the surface of the wafer 1 for prevention of damage to the electronic circuit and the bumps formed thereon. Since the rear surface of the wafer 1 is thinned by grinding, the metal electrodes 8 penetrate the wafer 1 in a thickness direction thereof to be formed into via electrodes 8A.

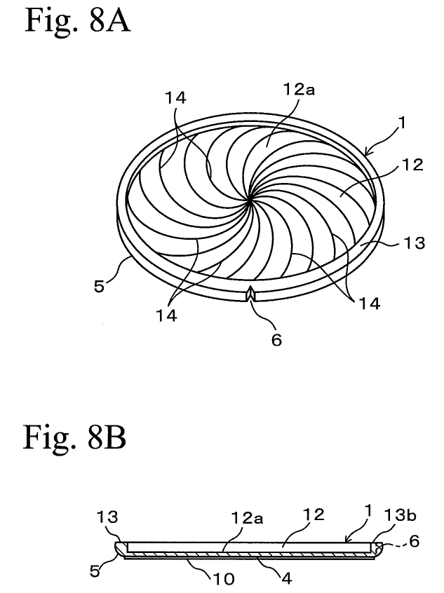

A portion thinned on the wafer 1 is not the entirety of the rear surface of the wafer 1, and is only region corresponding to a device forming region 4. Therefore, a recess, which is recessed on the device forming region 4, is formed on the rear surface of the wafer 1, and a ring-shaped protrusion having the same thickness as an initial thickness of the wafer is simultaneously formed on the peripheral extra region 5 around the recess as described below (see FIG. 8). Next, as shown in FIG. 2E, a thin layer of the rear surface of the wafer 1 subjected to the grinding is removed, and the via electrodes 8A project from the rear surface, so that rear surface side electrode portions 11 are formed.

In the above manner, the thickness of the wafer 1 on the device forming region 4 becomes a desired thickness. After that, the protective tape 10 is peeled from the wafer 1, the wafer 1 is divided by cutting the predetermined division lines 2, and divided plural semiconductor chips 3 are obtained. For example, one of the obtained semiconductor chips 3 is stacked on an interposer, and another of the obtained semiconductor chips 3 is stacked on one of the obtained semiconductor chips 3, so that the obtained semiconductor chips 3 are formed into a semiconductor package.

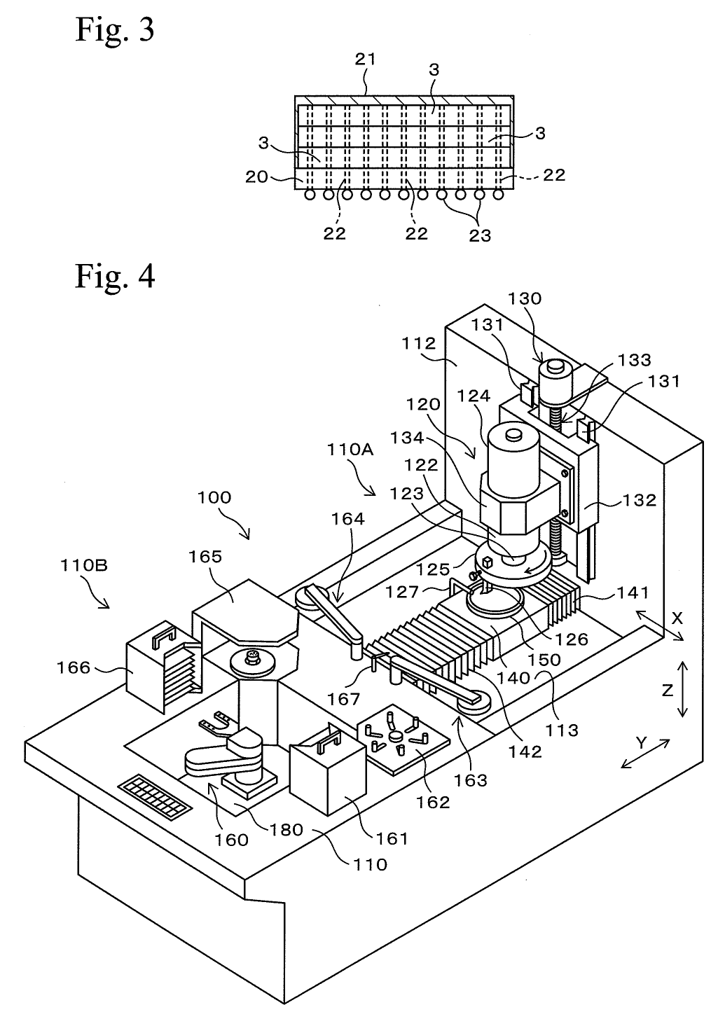

FIG. 3 shows a structural example of a semiconductor package in which three semiconductor chips 3 are stacked and molded on an interposer 20 by a resin 21. In the semiconductor chip 3 on the interposer 20, rear surface side electrode portions 11 are pressure-bonded on via electrodes 22 formed on the interposer 20 in the same manner as the semiconductor chip 3, so that electrical connection and fixing of the semiconductor chip 3 and the interposer 20 are performed so that they are stacked. In the semiconductor chips 3, the rear surface side electrode portions 11 of the upper semiconductor chip 3 are pressure-bonded on the bumps 7 of the lower semiconductor chip 3, so that electrical connection, stacking, and fixing of the semiconductor chips 3 are simultaneously performed. Bumps 23 which electrically connect to the via electrodes 22 are formed as electrical contact points to a substrate (not shown in FIG. 3).

### 3. Production Method for Semiconductor Chip

Next, a production method in which the plural semiconductor chips 3 are obtained from the wafer 1 shown in FIG. 1, that is, the wafer 1 including the bumps 7 having the heights unequal to each other shown in FIG. 2C will be specifically explained.

### 3.1. Process for Making Bump Height Uniform

The tips projecting from the surfaces of the bumps 7 are cut off and planarized by a cutting apparatus 100 shown in FIG. 4, so that the heights of the bumps 7 are made to be equal. The heights of the bumps 7 are controlled to be about 50 to 100 μm.

The cutting apparatus 100 will be explained with reference to FIG. 4. The cutting apparatus 100 is equipped with a rectangular parallelepiped pedestal 110. A wall portion 112 is provided at an end portion of the pedestal 110 in a longitudinal direction thereof and stands perpendicularly to a flat upper surface of the pedestal 110. In FIG. 4, the Y direction denotes a longitudinal direction of the pedestal 110, the X direction denotes a width direction of the pedestal 110, which is perpendicular to the longitudinal direction, and the Z direction denotes a vertical direction of the pedestal 110 which is perpendicular to the longitudinal direction. A processing area 110A for cutting the wafer 1 is provided from the middle portion of the longitudinal direction of the pedestal 110 to the wall portion 112 on the pedestal 110. A setting area 110B for providing a wafer 1 before processing and collecting a wafer 1 after processing is provided on a side opposite to the wall portion 112 on the pedestal 110.

A rectangular pit 113 is formed on the processing area 110A. A table base 140 is provided in the pit 113 and is reciprocated in the Y direction by a drive mechanism (not shown in FIG. 4). A vacuum-type chuck table 150 is provided on the table base 140 and is rotated around an axis extending in the Z direction (vertical direction). An upper surface of the chuck table 150 is a flat wafer holding surface. An chucking area for chucking the wafer 1 by chucking the above air during vacuum running is provided on the holding surface. Cornice-shaped covers 141 and 142 for preventing intrusion of dust and waste are stretchably provided on both sides of the moving direction of the table base 140 so as to cover the moving path of the table base 140.

A chuck table 150 is moved toward the wall portion 112 together with the table base 140, and is placed at a predetermined processing position. A cutting unit 120 is disposed above the processing position. The cutting unit 120 is elevatably mounted on the wall portion 112 of the pedestal 110 via a moving plate 132 and a guide rail 131. The cutting unit 120 is elevated by a carrying mechanism 133 driven by a motor 130.

The cutting unit 120 is equipped with a cylindrical spindle housing 122, a spindle 123, a motor 124, and a disc-shaped flange 125. The spindle housing 122 has an axis extending in the Z direction. The spindle 123 is coaxially and rotatably supported in the spindle housing 122. The motor 124 is fixed at the upper end portion of the spindle housing 122 and rotates the spindle 123. The flange 125 is coaxially fixed at the lower end of the spindle 123. The spindle housing 122 is fixed on the moving plate 132 via a block 134. The flange 125 is rotated by the motor 124 in the arrow direction shown in FIG. 4 (shown on an upper surface of the flange 125).

A turning tool 126 is removably mounted on a lower surface of the flange 125 and cuts the tips of the bumps 7. The turning tool 126 has a cutting edge composed of a hard material selected from the group consisting of diamond, cemented carbide, cubic boron nitride (CBN), or the like. An air nozzle 127 is disposed on the processing area 110A and removes cut waste by spraying high-pressure air on a cut surface of the wafer 1 (cut portion of the bump 7) which is held on the chuck table 150 and is cut by the turning tool 126.

A rectangular pit 180 is formed at the center of the setting area 110B. A moving robot 180 is a double-jointed link-type robot, which moves upward and downward and is disposed at the bottom portion of the pit 180. A supply cassette 161, a positioning pedestal 162, a rotating arm type supply arm 163, a collecting arm 164, a spinner type cleaning device 165, and a collecting cassette 166 are disposed around the moving robot 160 in a counterclockwise direction seen from above. The collecting arm 164 has the same structure as the supply arm 163. A cleaning nozzle 167 is provided between the supply arm 163 and the collecting arm 164 and cleans the chuck table 150 by spraying the cleaning water and the high-pressure air thereon.

In the above cutting apparatus 100, the tips of the bumps 7 that project from the surface of the wafer 1 are cut off as described below. Plural wafers 1 are stacked and provided in the supply cassette 161. One of the wafers 1 is moved to the positioning pedestal 162 by the moving robot 160 and is placed thereon. Next, the wafer 1, when the surface on which bumps 7 project therefrom face upward, is moved on the chuck table 150 which is held at a setting position proximate to the setting area 110B and which operates in a vacuum.

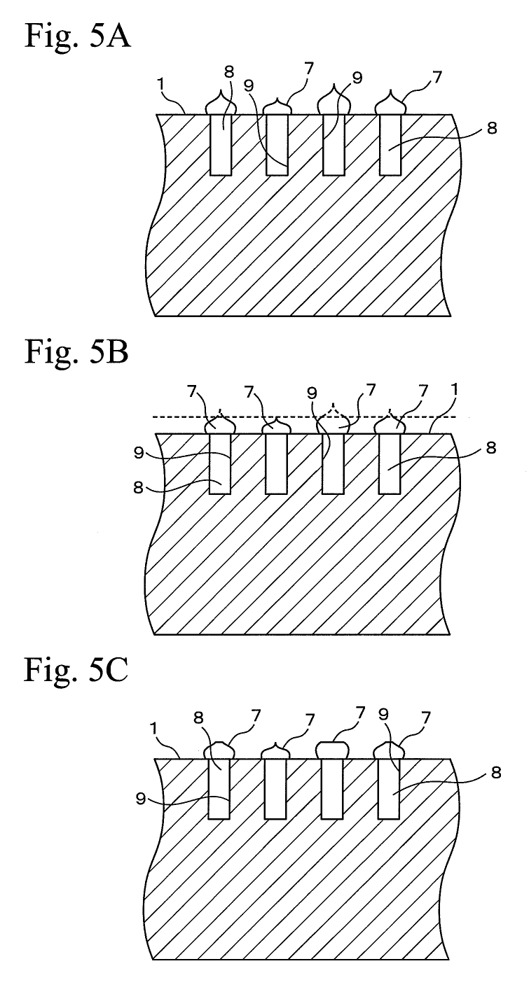

In the cutting unit 120, the flange 125 is rotated and the position of the Z direction is controlled such that a cutting depth of the turning tool 126 with respect to the bumps 7 is set at a predetermined value (which corresponds to 50 to 100 μm of the heights of the bumps 7 after the cutting is performed as described above). Next, the chuck table 150 chucking and holding the wafer 1 is moved toward the wall portion 112 at a predetermined speed, so that the tips of all the bumps 7 are cut and planarized by the rotating of the turning tool 126, and the heights of all the bumps 7 are made equal. FIGS. 5A to 5C show processes in which the tips of the bumps 7 having heights different from each other are cut, and the heights of the bumps 7 are thereby made equal. A dotted line denotes a cut surface that is cut by rotating of the turning tool 126, and the heights of the bumps 7 are made to be equal to each other.

In the cutting of the bumps 7, high-pressure air is sprayed from the air nozzle 127 to the wafer 1, so that cut waste is removed. Although the chuck table 150 is not rotated in the cutting of the bumps 7, there are cases in which the chuck table 150 is rotated. For example, in the cases in which a moving distance of the chuck table 150 is set to be short and in which a diameter of the rotation locus of the turning tool 126 is shorter than a diameter of the wafer 1, the chuck table 150 is rotated, so that a cut region of the wafer 1 which must be cut is disposed in a cutting region of the turning tool 126.

As described above, after the heights of the bumps 7 are made to be equal, the chuck table 150 is moved to the setting position, and the vacuum operation of the chuck table 150 is stopped. Next, the wafer 1 on the chuck table 150 is moved in the cleaning device 165 by the collecting arm 164, and is water-washed and dried by the cleaning device 165. Next, the wafer 1 is moved to the collecting cassette 166 and is provided therein. The cleaning water and the high-pressure air are sprayed from the cleaning nozzle 167 to the chuck table 150 stopped at the setting position, so that the chuck table 150 is cleaned.

### 3.2. Protective Tape Applying Process

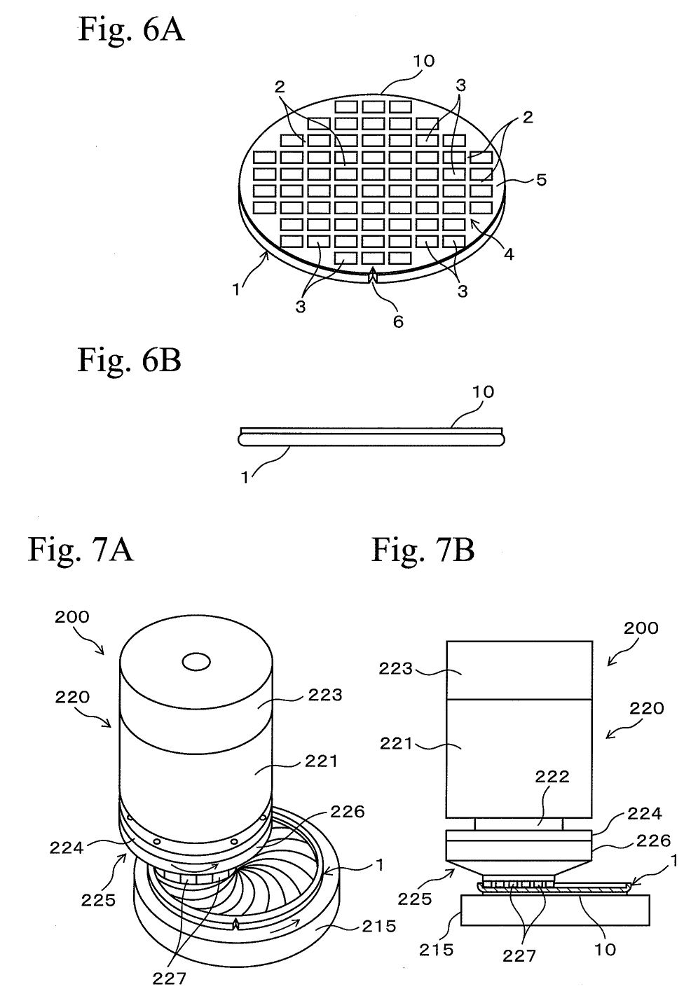

Next, as shown in FIG. 6, a protective tape 10 is applied to the surface of the wafer 1. A tape having a substrate and an adhesive coated on a surface of the substrate is preferably used as the protective tape 10. For example, the substrate is composed of a polyethylene resin and has a thickness of about 100 to 200 μm. The adhesive is acrylic and has a thickness of about 10 to 20 μm. As described above, the protective tape 10 is used for prevention of damages to the electronic circuit and the planarized bumps 7 which are formed on the surface of the wafer 1. When the amount by which the bumps 7 project from the surface of the wafer 1 is large, the substrate of the protective tape 10 is preferably thick and flexible and the thickness of the adhesive of the protective tape 10 corresponds to the heights of the bumps 7 in order to relax stresses loaded on the bumps 7.

### 2.3. Rear Surface Recess Forming Process

Next, in a rear surface recess forming process, only region on the rear surface of the wafer 1 corresponding to the device forming region 4 is ground and thinned by using a grinding apparatus 200 shown in FIG. 7, and a recess 12 shown in FIG. 8 is formed on the rear surface of the wafer 1. As shown in FIG. 2D, the depth of the recess 12 is a depth such that the metal electrode 8 is exposed at a ground surface. The grinding apparatus 200 shown in FIG. 7 is equipped with a chuck table 215 holding the wafer 1 and a grinding unit 220 disposed above the chuck table 215. The chuck table 215 is the same vacuum chuck type as that of the chuck table 150 and has an chucking area for chucking and holding the wafer 1 on a flat upper surface thereof.

The grinding unit 220 is equipped with a cylindrical spindle housing 221, a spindle 222, a motor 223, and a disc-shaped flange 224. The spindle housing 221 has an axis extending in the Z direction. The spindle 222 is coaxially and rotatably supported in the spindle housing 221. The motor 223 is fixed at the lower end of the spindle housing 221 and rotates the spindle 222. The flange 224 is coaxially fixed at the lower end of the spindle 222. A cup wheel 225 is removably mounted to the flange 224 by a screw or the like.

The cup wheel 225 has a disc-shaped frame 226 and plural grind stones 227. The frame 226 has a conical lower portion. The grinding stones 227 are fixed at a lower end surface of the frame 226 so as to be circularly arranged along the peripheral portions of the lower end surface thereof. For example, the grinding stones 227 are composed of a glassy sintered material (called “vitrified”) that is mixed with diamond abrasive grains and is sintered. The grinding stones 227 preferably include abrasive grains having a grain size of about #280 to #8000 for grinding silicon wafers. As shown in FIG. 7B, grinding diameters of the cup wheel 225, that is, diameters of peripheral edges of the grinding stones 227 are approximately equal to or slightly larger than the radius of the device forming region 4 of the wafer 1.

In the above grinding apparatus 200, the chuck table 215 chucks and holds the wafer 1 and is rotated so that the surface of the wafer 1 on which the protective tape 10 is applied closely contacts the upper surface of the chuck table 215 and the wafer 1 is concentric with the chuck table 215. Next, the entirety of the grinding unit 220 is moved downward, the cup wheel 225 is rotated at a speed of about 2000 to 5000 rpm, and the grinding stones 227 abut the device forming region 4 of the rear surface of the wafer 1, so that the device forming region 4 is thinned by grinding. Grinding water is supplied on the grinding surface of the wafer 1. The grinding stones of the cup wheel 225 are placed with respect to the wafer 1 such that a grinding locus passes from a peripheral edge (border line between the device forming region 4 and the peripheral extra region 5) of the device forming region 4 to a portion which slightly exceeds the center of the wafer 1. As a result, only the region on the rear surface corresponding to the device forming region 4 is thinned by grinding.

After the region on the rear surface corresponding to the device forming region 4 is thinned by grinding so as to reach the metal electrodes 8, the grinding unit 220 is moved upward, the grinding stones 227 are separated from the wafer 1, and the rotating of the chuck table 215 is stopped. As shown in FIG. 8, in the grinding, a recess 12 is formed on a region on the rear surface of the wafer 1 corresponding to the device forming region 4, and a ring-shaped protrusion 13 having the initial thickness of the wafer 1 and projecting from the rear surface is formed on the rear surface corresponding to the peripheral extra region 5. As a result, the entirety of the wafer 1 is processed to be recessed in cross section. For example, the thickness of the recess 12 is about 200 to 100 μm or about 50 μm.

As shown in FIG. 8A, a grinding mark 14 which has plural arc shapes extending radially from the center and is formed by the grinding stones 227 remains on a bottom surface 12a of the recess 12. The grinding mark 14 is a locus formed by grinding by the abrasive grains in the grinding stones 227, and is a mechanical damage layer including microcracks or the like. The same damage is formed at the inner peripheral surface of the ring-shaped protrusion 13. The ground end surface (not shown in FIG. 8) of the metal electrode 8 is exposed at the bottom surface 12a of the recess 12 shown in FIG. 8, and the metal electrodes 8 are formed into the via electrodes 8A penetrating the wafer 1 in the thickness direction of the wafer 1 as shown in FIG. 2D.

### 2.4. Etching Process

Next, the rear surface 1 of the wafer 1 is subjected to etching, and a thin layer of the bottom surface 12a of the recess 12 is removed so that the via electrodes 8A project from the rear surface and the rear surface electrode portions 11 are formed as shown in FIG. 2E. The amount by which the rear surface electrode portion 11 projects is approximately equal to the amount of thickness of the removed layer at the rear surface, and is, for example, about 5 μm. The etching is preferably plasma etching which uses a gas that reacts the silicon wafer material to remove it but does not react with the via electrodes 8A.

In the plasma etching, an atmosphere in a vessel in which the wafer 1 is provided is composed of typical silicon etching gas (for example, fluorine type gas such as CF₄ or SF₆) and a plasma discharge is performed. In the plasma etching, the protective tape 10 may be maintained to be applied on the surface of the wafer 1 when the protective tape 10 is sufficiently heat-resistant, and the protective tape 10 may be peeled from the surface of the wafer 1 beforehand when the protective tape 10 is not sufficiently heat-resistant.

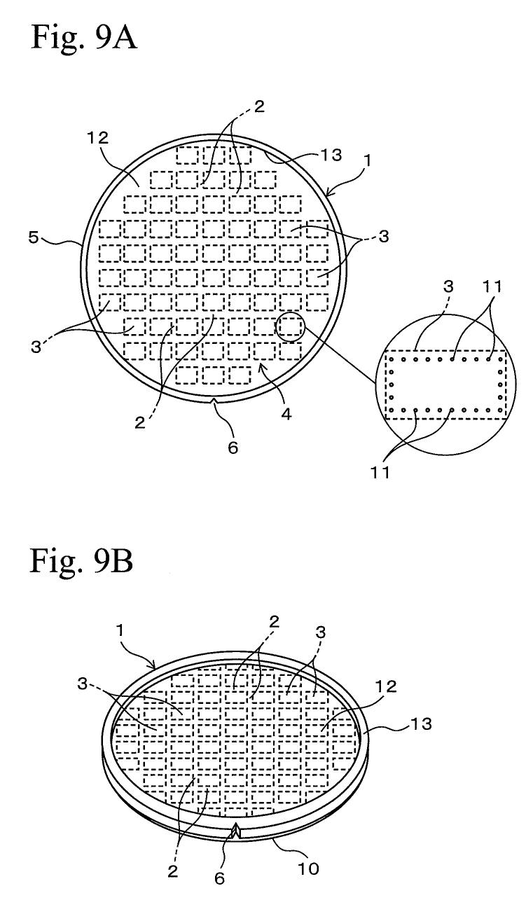

By the above etching, the via electrodes 8A project from the bottom surface 12a of the recess 12 of the wafer 1, and the rear surface electrode portions 11 are formed. In addition, the mechanical damage layer caused by the above grinding mark 14 is removed. The mechanical damage layer may cause stress concentration and thereby may cause generation of cracks and breakage. However, since the mechanical damage layer is removed, the above problems do not occur, and the strength of the wafer 1 or the divided semiconductor chips 3 are improved. FIG. 9 shows the rear surface of the wafer 1 on which the rear surface recess electrode portions 11 project by the etching and the grinding mark 14 is removed. The etching for removing the mechanical damage layer is not limited to the plasma etching, and the etching may be typical wet etching.

### 2.5. Dividing Process

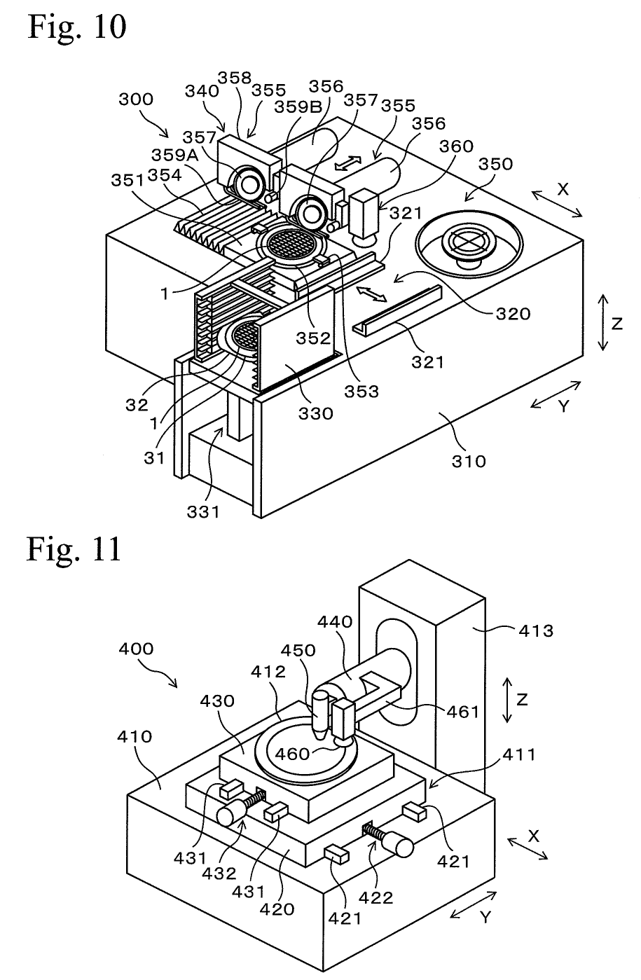

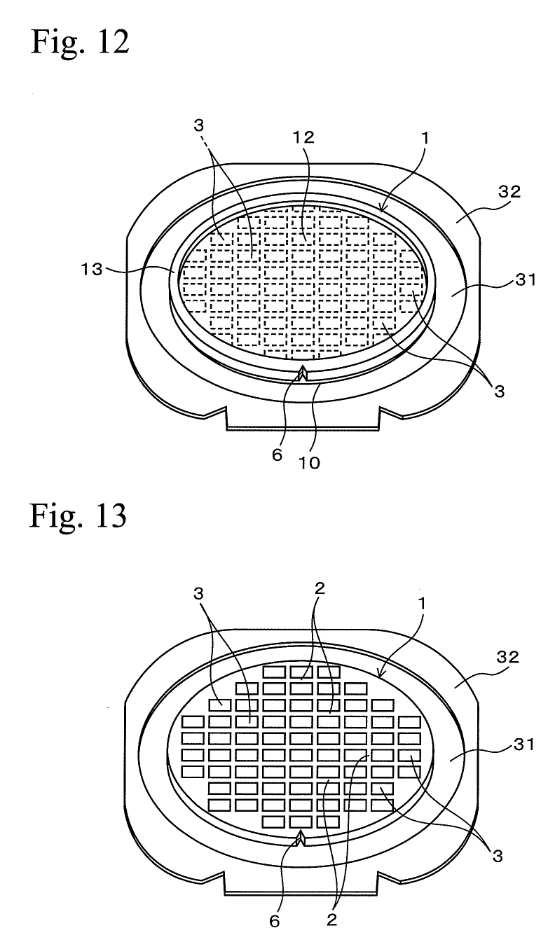

As described above, the processing of the wafer 1 is finished before the dividing process. Next, all the predetermined division lines 2 of the wafer 1 are cut, so that the wafer 1 is divided into semiconductor chips 3. A dicing apparatus 300 using a cutting blade shown in FIG. 10 and laser beam machining apparatus shown in FIG. 11 are preferably used as an apparatus for dividing the wafer 1 into the semiconductor chips 3. When the wafer 1 is supplied to the above dividing apparatuses, a dicing tape 31 and a dicing frame 32 shown in FIG. 12 are used as a jig for supporting a wafer.

The dicing tape 31 has a substrate and an adhesive coated on a surface of the substrate. For example, the adhesive is composed of polyvinylchloride and has a thickness of about 100 μm. The adhesive is composed of acrylic resin and has a thickness of about 5 μm. The dicing frame 32 which is ring-shaped and has an inner diameter larger than the diameter of the wafer 1 is applied to an adhesive surface of the dicing tape 31. The wafer 1 is applied on the adhesive surface of the dicing tape 31 in the dicing frame 32 so that the rear surface of the wafer 1 on which the recess 12 is formed is exposed as shown in FIG. 12. In this case, the protective tape 10 is applied to the surface which is an applying surface. For example, the dicing frame 32 is composed of a metal plate having rigidity, and handling (for example, moving) of the wafer 1 is easily performed by the dicing frame 32.

The dicing apparatus 300 is equipped with an approximately rectangular parallelepiped pedestal 310. A positioning mechanism 320 is provided on a flat upper surface of the pedestal 310. A cassette 330, a dicing mechanism 340, and a cleaning unit 350 are disposed around the positioning mechanism 320 in a clockwise direction seen from the above. An image recognition camera 360 is provided above the positioning mechanism 320, photographs the surface of the wafer 1, and recognizes the predetermined division lines 2 which are intended to be cut.

Plural dicing frames 32 holding the wafers 1 via the dicing tapes 31 as described above are provided in the cassette 330 so as to be approximately horizontally stacked such that the wafers 1 face upwardly. As shown in FIG. 12, when the wafer 1 is applied on the dicing tape 31 such that the rear surface of the wafer 1 on which the recess 12 is formed is exposed, and the cutting by the cutting blade is performed from the rear surface of the wafer 1, it is necessary to the recognize the predetermined division lines 2, which are formed on the surface of the wafer 1, from the rear surface of the wafer 1. Therefore, an infrared camera is preferably used as the image recognition camera 360.

The cassette 330 is mounted on an elevating mechanism 331 which elevates the wafers 1 therein one step at a time. The dicing frame 32 moved to the lowest step by the elevating mechanism 331 is ejected from the cassette 330. The dicing frame 32 is moved to the dicing mechanism 340 via the positioning mechanism 320, and the wafer 1 is cut and divided into plural semiconductor chips 3 by the dicing mechanism 340. The wafer 1 moved from the cassette 330 to the positioning mechanism 320 is held at a predetermined position by a pair of guide bars 321, and the positions of the predetermined division lines 2 are recognized by the image recognition camera 360 thereat. The dicing mechanism 340 is controlled based on image data photographed by the image recognition camera 360.

The condition of the wafer 1 is maintained such that the divided plural semiconductor chips 3 are applied on the dicing tape 31. After that, the dicing frame 32 is moved to a cleaning unit 350 via the positioning mechanism 320, and the wafer 1 when the plural semiconductor chips 3 are divided is cleaned by the cleaning unit 350. The cleaned wafer 1 is returned to the cassette 330 via the positioning mechanism 320. The above moving of the wafer 1 is performed by a moving robot (not shown in FIG. 10).

The dicing mechanism 340 is equipped with a table base 351, a vacuum chuck type chuck table 352, and two cutting units 355. The table base 351 is provided on the pedestal 310 so as to reciprocate in an X direction. The chuck table 352 is provided on the table base 351 so as to rotate around a Z direction as a rotation axis. The two cutting units 355 are disposed above the chuck table 352 so as to be parallel in an X direction.

The wafer 1 is chucked and held on a flat upper surface of the chuck table 352 via the dicing tape 31. A clamp 353 is provided on the table base 315 which removably holds the dicing frame 32. A cornice-shaped cover 354 is stretchably provided at both end portions in the moving direction of the table base 351 so as to cover the moving path of the table base 351 and prevent intrusion of dust and waste.

The each cutting unit 355 is equipped with a cylindrical spindle housing 356 and a cutting blade 357. The spindle housing 356 is provided such that an axial direction is parallel to a Y direction. The cutting blade 357 is mounted to a spindle (not shown in FIG. 10) provided in the spindle housing 356. The spindle housing 356 is supported by a frame (not shown in FIG. 10) provided on the pedestal 310 so as to reciprocate in the axis direction, that is, in the Y direction and be elevated in the Z direction. Each cutting unit 355 is moved in the above directions by a driving mechanism (not shown in FIG. 10). A blade cover 358 is mounted at an end portion of the spindle housing 356 proximate to the cutting blade 357. Cutting water nozzles 359A and 359B are mounted on the blade cover 358 and supply cutting water toward the cut portion of the wafer 1.

In the above structured dicing mechanism 340, the wafer 1 is held on the chuck table 352 via the dicing table 31, the chuck table 352 is rotated and the predetermined division lines 2 are set to the cutting blade 357. After that, the cutting blade 357 is moved downward and the table base 351 is moved in the X direction, so that the cutting blade 357 cuts the predetermined division lines 2 and the wafer 1 is cut along one predetermined division line 2.

In the dicing mechanism 340, by appropriate combination with the movements of the two cutting units 355 in the Y direction and the Z direction and the rotation of the chuck table 352, all the predetermined division lines 2 are cut. The cutting depth of the cutting blade 357 is set such that the cutting blade 357 penetrates the wafer 1 and slightly cuts the protective tape 10.

Since the dicing mechanism 340 has the two cutting units 355, for example, the cutting blades 357 of the two cutting units 355 are shifted such that the distance between the axial directions (Y directions) thereof corresponds to that between the predetermined division lines 2, so that two predetermined division lines 2 are cut by one movement in the X direction.

The cutting of the predetermined division lines 2 described above may be performed after the wafer 1 is planarized by removing the ring-shaped protrusion 13. For example, the removal of the ring-shaped protrusion 13 is performed such that the grinding stones rotated as shown in FIG. 7 are abutted to the end surface 13b (shown in FIG. 8B) of the rear surface of the ring-shaped protrusion 13 and the ring-shaped protrusion 13 is removed by grinding, or the overall peripheral extra region 5 including the ring-shaped protrusion 13 is cut to be separated from the device forming region 4 by using the above dicing apparatus 300.

After the wafer 1 is planarized by removing the ring-shaped protrusion 13, as shown in FIG. 13, the wafer 1 is applied to the dicing tape 31 so that the surface on which the semiconductor chips 3 are formed is exposed, and the wafer 1 can be set on the chuck table 352 in the above condition. In this case, since the predetermined division lines 2 can be photographed by a typical camera such as a charge-coupled device (CCD) camera, it is not necessary to use an infrared camera. When the wafer 1 is held on the chuck table 352 in the condition in which the rear surface of the wafer 1 is exposed, an infrared camera is necessary. However, the ring-shaped protrusion 13 is not obstructive when the predetermined division lines 2 are cut.

A laser beam machining apparatus 400 shown in FIG. 11 is equipped with a pedestal 410, an XY moving table 411, and a vacuum chuck type chuck table 412. The XY moving table 411 is horizontally movably provided on the pedestal 410 in an X direction and a Y direction. The chuck table 412 is disposed horizontally on the XY moving table 411. The wafer 1 is chucked and held on the chuck table 412 via the dicing tape 31 on which the dicing frame 32 is applied. The wafer 1 is cut by laser beam emitted downward from a laser nozzle 450 disposed thereabove. The laser beam emitted from the laser nozzle 450 is oscillated by an YAG laser oscillator or the like. The output power is advantageously 1 to 5 W and the wavelength is advantageously 1064 nm.

The XY moving table 411 has an X axis base 420 and a Y axis base 430. The X axis base 420 is provided on the pedestal 410 via a pair of guide rails 421 to be movable in the X direction. The Y axis base 430 is provided on the X axis base 420 via a pair of guide rails 431 to be movable in the Y direction. The X axis base 420 is reciprocated in the X direction by an X axis driving mechanism 422. The Y axis base 430 is moved in the Y direction by a Y axis driving mechanism 432. The chuck table 412 is rotatably provided on the Y axis base 430, so that the chuck table 412 is moved in the X direction and the Y direction by the movements of the X axis base 420 and the Y axis base 430. [0069] The laser nozzle 450 is mounted at a tip of a cylindrical processing shaft 440 extending in the Y direction. The processing shaft 440 is elevatably provided on a column 413 secured on the pedestal 410. The distance between the laser nozzle 450 and the wafer 1 held on the chuck table 412 is appropriately controlled by the elevating of the processing shaft 440. An image recognition camera 460 which is the same as that of the dicing apparatus 300 shown in FIG. 10 is provided on the processing shaft 440 via an arm 461. The wafer cutting actions by the movement of the laser nozzle 450 is controlled based on image data photographed by the image recognition camera 460.

By the above processes, the divided semiconductor chips 3 are obtained from the wafer 1 shown in FIG. 1. For example, as shown in FIG. 3, the plural semiconductor chips 3 are stacked on the interposer 20, so that the semiconductor package is obtained.

In the production method for the semiconductor chips of the embodiment, only the rear surface of the device forming region 4 of the wafer 1 is thinned by the grinding before the dividing process for dividing the wafer 1 into the semiconductor chips 3, and the ring-shaped protrusion 13 having the initial thickness of the wafer 1 is formed on the peripheral extra region 5 around the device forming region 4. Therefore, the wafer 1 is thinned, but the rigidity of the wafer 1 is ensured by the ring-shaped protrusion 13. Therefore, movement of the wafer 1 to the etching process for forming the rear surface electrode portions 11 by projecting the via electrodes 8A from the rear surface of the wafer 1 and the etching process can be easily and smoothly performed. The movement of the wafer 1 to the dividing process after that can be safely performed without breaking the wafer 1. As a result, productivity and yield ratio can be improved.

What is claimed is:

1. A production method for obtaining a stacked device from a wafer, the wafer comprising:
a device forming region formed on a surface having plural devices formed thereon, the devices having surfaces and thicknesses;
a peripheral extra region surrounding the device forming region; and
plural metal electrodes embedded in the surfaces of the devices and having thicknesses which are equal to or larger than the thicknesses of the devices,
the method comprising:
a protective tape applying process for applying a protective tape to the surface of the wafer;
a rear surface recess forming process for thinning only a region, which corresponds to the device forming region, on a rear surface by grinding, thereby forming a recess on the rear surface, forming a ring-shaped protrusion projecting from the rear surface on the peripheral extra region, and exposing the metal electrodes at the rear surface;
an etching process for removing mechanical damage, which is provided to the recess by the grinding, by etching to the recess, and forming a rear surface side electrode portion by projecting the exposed metal electrodes from a bottom surface of the recess; and
a dividing process for dividing the wafer into the devices.

2. A production method for a stacked device according to claim 1, wherein the dividing process is performed while the rear surface of the wafer is exposed and held.

3. A production method for a stacked device according to claim 1, wherein the dividing process is performed after removing the ring-shaped protrusion on the peripheral extra region.
